(19) United States
(12) Patent Application Publication
(10) Pub. No.: US 2026/0052850 A1
(43) Pub. Date: Feb. 19, 2026

(54) ORGANIC LIGHT EMITTING APPARATUS AND METHOD OF MANUFACTURING THE SAME

(71) Applicant: CANON KABUSHIKI KAISHA, Tokyo (JP)

(72) Inventors: SATOSHI INAI, Kanagawa (JP); TAKASHI USUI, Kanagawa (JP)

(21) Appl. No.: 19/294,895

(22) Filed: Aug. 8, 2025

(30) Foreign Application Priority Data
Aug. 14, 2024 (JP) 2024-135200

(51) Int. Cl. H10K 59/122; H10K 59/12

(52) U.S. Cl. CPC H10K 59/122; H10K 59/1201

(57) ABSTRACT

Some aspects of the embodiments relate to an organic light emitting apparatus in which an insulating layer that electrically insulates a plurality of first electrodes has a three-layer configuration, a first insulating layer and a third insulating layer have a material different from a material of a second insulating layer, and an angle of a side of the first insulating layer and an angle of a side of the third insulating layer with respect to a lower surface of a first electrode are both larger than an angle of a side of the second insulating layer with respect to the lower surface of the first electrode.

### BACKGROUND

### Field of the Technology

The aspect of the embodiments relates to an organic light emitting apparatus and a method of manufacturing the organic light emitting apparatus.

### Description of the Related Art

In recent years, a display apparatus has been known which uses an organic electroluminescent element (hereinafter, referred to as an “organic EL element”) as an electroluminescent element. A typical organic EL element has a structure in which pixel regions are electrically isolated from each other by an insulating layer made of an insulating material, allowing light emission driving independently for each pixel. However, with higher density of pixels of a display apparatus using an organic EL element, an issue has surfaced of leakage current through an organic layer provided in common between adjacent pixels in proximity to each other. The leakage current between adjacent pixels causes light emission in a pixel that is not intended to emit light, which is a factor in deterioration of light emission characteristics, such as color crosstalk and low light emission efficiency. As a configuration for addressing that issue, Japanese Patent Laid-Open No. 2023-164291 describes a structure in which a groove is disposed outside an element aperture in the anode of an organic EL element to reduce leakage current between adjacent pixels.

Japanese Patent Laid-Open No. 2023-164291 does not describe the shape of a side surface of an insulating layer.

### SUMMARY

Thus, the configuration described in Japanese Patent Laid-Open No. 2023-164291 has a potential to result in insufficient reduction of leakage current between adjacent pixels depending on the shape of a side surface of an insulating layer. Occurrence of leakage current causes light emission in a pixel that is not intended to emit light, resulting in deterioration of light emission characteristics.

According to an aspect of the embodiments, a light emitting apparatus includes a substrate, a first electrode disposed over the substrate, an insulating layer disposed over the substrate, the insulating layer having an aperture over the first electrode and covering an outer periphery of the first electrode, an organic compound layer covering the first electrode and the insulating layer, and a second electrode disposed over the organic compound layer. The insulating layer includes a first insulating layer, a second insulating layer, and a third insulating layer in that order from the substrate side. The second insulating layer is different in material from both the first insulating layer and the third insulating layer. A side surface S₁ of the first insulating layer, a side surface S₂ of the second insulating layer, and a side surface S₃ of the third insulating layer are all in contact with the organic compound layer, the side surfaces S₁, S₂, and S₃ surrounding the aperture. An angle θ₁ of the side surface S₁ of the first insulating layer with respect to a lower surface of the first electrode and an angle θ₃ of the side surface S₃ of the third insulating layer with respect to the lower surface of the first electrode are both larger than an angle θ₂ of the side surface S₂ of the second insulating layer with respect to the lower surface of the first electrode.

According to another aspect of the embodiments, a method of manufacturing an organic light emitting apparatus includes forming a first insulating film, a second insulating film, and a third insulating film in that order over a substrate provided with a first electrode, and forming a third insulating layer, a second insulating layer, and a first insulating layer by etching the third insulating film, the second insulating film, and the first insulating film, respectively. The first electrode is exposed in the etching of the first insulating film. In the etching of the third insulating film, the second insulating film, and the first insulating film, an etching rate of the second insulating film is lower than an etching rate of the third insulating film.

Further features of the disclosure will become apparent from the following description of embodiments with reference to the attached drawings. The following description of embodiments is described by way of example.

### BRIEF DESCRIPTION OF THE DRAWINGS

FIG. 1 is a schematic cross sectional view of an organic light emitting apparatus according to an embodiment.

FIG. 2 is a schematic plan view of the organic light emitting apparatus of FIG. 1.

FIG. 3 is a partially enlarged view of an insulating layer of the organic light emitting apparatus of FIG. 1.

FIGS. 4A and 4B illustrate a process of manufacturing the organic light emitting apparatus of FIG. 1.

FIG. 5 illustrates a process of manufacturing the organic light emitting apparatus of FIG. 1.

FIG. 6 illustrates a process of manufacturing the organic light emitting apparatus of FIG. 1.

FIG. 7 illustrates a process of manufacturing the organic light emitting apparatus of FIG. 1.

FIG. 8 illustrates a process of manufacturing the organic light emitting apparatus of FIG. 1.

FIG. 9 is a schematic cross sectional view illustrating a side surface of an insulating layer of an organic light emitting apparatus according to some embodiments.

FIG. 10 illustrates a process of manufacturing the organic light emitting apparatus of FIG. 9.

FIG. 11 is a schematic view illustrating an example of a display apparatus according to some embodiments.

FIG. 12A is a schematic view illustrating an example of an imaging device according to the embodiment. FIG. 12B is a schematic view illustrating an example of an electronic apparatus according to some embodiments.

FIG. 13A is a schematic view illustrating an example of a display apparatus according to some embodiments. FIG. 13B is a schematic view illustrating an example of a foldable display apparatus.

FIG. 14 is a schematic view illustrating an example of a lighting apparatus according to some embodiments.

FIG. 15A is a schematic view illustrating an example of an automobile including a vehicular lamp according to the embodiment. FIG. 15B is a schematic view illustrating an example of the automobile including the vehicular lamp according to some embodiments.

FIG. 16A is a schematic view illustrating an example of a wearable apparatus according to the embodiment. FIG. 16B is an example of a wearable apparatus according to the embodiment, and is a schematic view illustrating a form including an imaging device.

FIG. 17A is a schematic view illustrating an example of an image forming apparatus according to the embodiment. FIG. 17B is a schematic view illustrating an example of an exposure light source of the image forming apparatus according to the embodiment. FIG. 17C is a schematic view illustrating an example of an exposure light source of the image forming device according to the embodiment.

### DESCRIPTION OF THE EMBODIMENTS

An aspect of an embodiment is characterized in that, in an organic light emitting apparatus having a plurality of pixels, an insulating layer that insulates and separates pixels from each other has a three layer structure, in which an inclination angle of a central insulating layer is smaller than inclination angles of lower and upper insulating layers along a side surface forming an aperture on a first electrode, reducing leakage current between the pixels.

Hereinafter, an organic light emitting apparatus according to the present embodiment and a method of manufacturing the organic light emitting apparatus according to embodiments will be described.

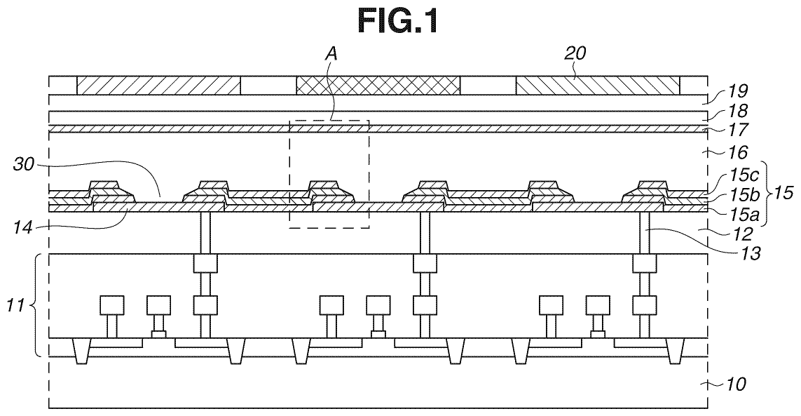

FIG. 1 is a schematic cross sectional view of a substrate of the organic light emitting apparatus according to an aspect of the present embodiment in a thickness direction.

A drive circuit layer 11 is provided over a substrate 10, and a planarized first planarization layer 12 made of an insulating material is provided on the drive circuit layer 11. Organic electroluminescent (EL) elements are provided over the first planarization layer 12. An organic EL element has a configuration in which a first electrode 14 as an anode, an insulating layer 15, an organic compound layer 16, and a second electrode 17 as a cathode are stacked in that order.

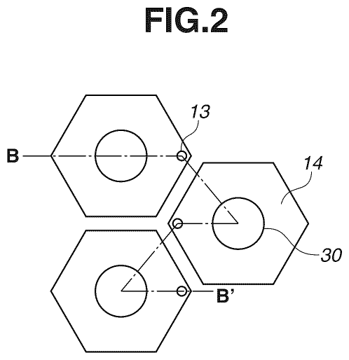

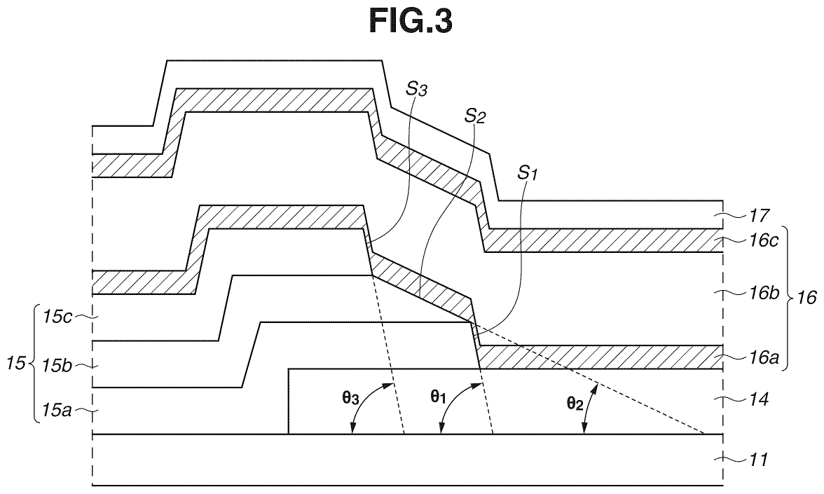

FIG. 2 illustrates an example of a planar configuration diagram of a display apparatus according to the present embodiment. FIG. 1 corresponds to a schematic cross sectional view of a B-B′ portion in FIG. 2. In order to clarify the positional relationship, conductive plugs 13, first electrodes 14, and apertures 30 of insulating layers 15 are drawn, and the other components are omitted. A first electrode 14 may have a circular shape in a plan view. An aperture 30 may be a polygon, such as a hexagon. FIG. 3 is an enlarged view of a region A surrounded by a broken line in FIG. 1.

In the present embodiment, an insulating layer 15 that electrically insulates and separates pixels from each other covers the outer periphery of the upper surface of a first electrode 14, and is formed of a stacked structure having a first insulating layer 15a, a second insulating layer 15b, and a third insulating layer 15c in that order from the side of the substrate 10. The first insulating layer 15a is disposed over a surface of the first planarization layer 12 that is not in contact with the first electrode 14 and over end portions of the first electrode 14. The second insulating layer 15b is disposed above the surface of the first planarization layer 12 that is not in contact with the first electrode 14 and above the end portions of the first electrode 14 via the first insulating layer 15a. Further, the third insulating layer 15c is disposed above the surface of the first planarization layer 12 that is not in contact with the first electrode 14 and over the end portions of the first electrode 14 via the first insulating layer 15a and the second insulating layer 15b.

The organic compound layer 16 includes a first organic compound layer 16a including at least one of a hole injection layer and a hole transport layer, a second organic compound layer 16b having a light emitting function, and a third organic compound layer 16c including at least one of an electron injection layer and an electron transport layer. The first organic compound layer 16a is disposed over the first electrode 14 and the insulating layer 15, and the second organic compound layer 16b is disposed over the first electrode 14 and the insulating layer 15 via the first organic compound layer 16a. The third organic compound layer 16c is disposed over the first electrode 14 and the insulating layer 15 via the first organic compound layer 16a and the second organic compound layer 16b. The thickness of each of these organic compound layers can be, for example, one nanometer (nm) to 500 nm.

The second electrode 17 is arranged over the first electrode 14 and the insulating layer 15 via the organic compound layer 16.

The shapes of side surfaces of the first insulating layer 15a, the second insulating layer 15b, and the third insulating layer 15c will now be described.

As illustrated in FIG. 3, the first insulating layer 15a has a side surface S₁, the second insulating layer 15b has a side surface S₂, and the third insulating layer 15c has a side surface S₃, along the aperture 30. An angle θ₁ of the side surface S₁ of the first insulating layer 15a with respect to the lower surface of the first electrode 14 is larger than an angle θ₂ of the side surface S₂ of the second insulating layer 15b with respect to the lower surface of the first electrode 14, and an angle θ₃ of the side surface S₃ of the third insulating layer 15c with respect to the lower surface of the first electrode 14 is larger than the angle θ₂ (θ₁>θ₂, θ₃>θ₂).

That is, by making the side surface S₁ of the first insulating layer 15a and the side surface S₃ of the third insulating layer 15c steep, the thickness of the first organic compound layer 16a having low resistance can be reduced. This can reduce leakage current between adjacent pixels. In addition, the configuration that the side surface S₁ and the side surface S₃ are steeply inclined improves the aperture ratio of the element. In order to produce such an effect, in one embodiment, each θ₁ and θ₃ is to be larger than 50° and smaller than 90°.

On the other hand, the configuration that the side surface S₂ is gently inclined compared with the side surfaces S₁ and S₃ makes the thickness of the organic compound layer 16 too thin, allowing reduction of occurrences of leakage current between the first electrode 14 and the second electrode 17. In order to produce such an effect, in one embodiment, θ₂ is to be larger than 0° and smaller than or equal to 50°.

In one embodiment, the thicknesses of the first insulating layer 15a and the third insulating layer 15c is to be larger than the thickness of the first organic compound layer 16a. In particular, the thicknesses of the first insulating layer 15a and the third insulating layer 15c can be larger than 1.4 times the thickness of the first organic compound layer 16a. This can reduce the thickness of the first organic compound layer 16a provided along the side surface S₁ of the first insulating layer 15a and the side surface S₃ of the third insulating layer 15c, allowing reduction of leakage current between adjacent pixels.

In one embodiment, the thicknesses of the first insulating layer 15a and the third insulating layer 15c is to be smaller than the thickness of the organic compound layer 16. This can reduce occurrences of leakage current between the first electrode 14 and the second electrode 17, which is caused by a too thin thickness of the organic compound layer 16 provided along the side surface S₁ of the first insulating layer 15a and the side surface S₃ of the third insulating layer 15c.

The first organic compound layer 16a may include an organic light emitting layer and a charge generation layer, in addition to at least one of the hole injection layer and the hole transport layer. The charge generation layer can be made thin by the steep inclinations of the side surface S₁ of the first insulating layer 15a and the side surface S₃ of the third insulating layer 15c. This can increase the resistance of the charge generation layer while the charge generation layer has low resistance like the hole injection layer and the hole transport layer, whereby leakage current between adjacent pixels can be reduced.

The first insulating layer 15a and the second insulating layer 15b are formed of different materials from each other.

Further, the second insulating layer 15b and the third insulating layer 15c are formed of different materials from each other. This makes it easy to process an article with the relationship of θ₁>θ₂ and θ₃>θ₂ by dry etching without changing the process conditions.

If the first insulating layer 15a, the second insulating layer 15b, and the third insulating layer 15c are all made of the same material, the etching conditions to process an article with the relationship of θ₁>θ₂ and θ₃>θ₂ by dry etching are switched in the middle of the process. Switching of the dry etching conditions causes generation of particles, resulting in decrease in yield.

In dry etching, the thickness of a layer removed per unit time is defined as an etching rate. If two stacked films formed of materials having different etching rates, patterned by a photolithography method, and provided over a substrate are continuously etched under a certain dry etching condition, a difference occurs in angle of a side surface of each of the two stacked films with respect to the substrate. If the etching rate of the lower film is lower than the etching rate of the upper film of the two stacked films provided over the substrate, the angle of the side surface of the upper film with respect to the substrate is larger than the angle of the side surface of the lower film with respect to the substrate. In contrast, if the etching rate of the lower film is higher than the etching rate of the upper film of the two stacked films provided over the substrate, the angle of the side surface of the upper film with respect to the substrate is smaller than the angle of the side surface of the lower film with respect to the substrate.

In the present embodiment, in a case where the etching rate of the second insulating layer 15b is lower than the etching rate of the first insulating layer 15a, θ₁ is larger than θ₂. In addition, in a case where the etching rate of the second insulating layer 15b is lower than the etching rate of the third insulating layer 15c, θ₃ is larger than θ₂. In this way, in a case where the first insulating layer 15a and the second insulating layer 15b are made of different materials and the second insulating layer 15b and the third insulating layer 15c are made of different materials, the shape of the present embodiment can be achieved by processing an article without switching the dry etching conditions, preventing decrease in yield due to the generation of particles.

As described above, in the present embodiment, the etching rate of the second insulating layer 15b is to be lower than the etching rates of the first insulating layer 15a and the third insulating layer 15c. For example, in a case where a fluorocarbon-based gas without hydrogen is used as the dry etching gas, a silicon oxide film (SiOₓ) can be employed as the first insulating layer 15a and the third insulating layer 15c, and a silicon nitride film (SiNₓ) can be used as the second insulating layer 15b. Here, the fluorocarbon-based gas without hydrogen refers to a fluorocarbon gas containing no hydrogen atoms, and examples thereof include tetrafluoromethane (CF₄), hexafluorocthane (C₂F₆), hexafluorobutadiene (C₄F₆), octafluorocyclobutane (C₄F₈), and octafluorocyclopentene (C₅F₈). However, the expression “containing no hydrogen atoms” means that hydrogen atoms are not intentionally contained, and does not exclude a case where a small number of hydrogen atoms are contained in a treatment chamber during dry etching. In addition, in dry etching, an oxygen (O₂) gas, or an argon gas (Ar) or a nitrogen (N₂) gas as a diluent gas may be used.

The first insulating layer 15a and the third insulating layer 15c may be made of the same material. Under that condition, through dry etching of the insulating layer 15 without switching of the dry etching conditions, the angles θ₁ and θ₃ can be similar. This makes it possible to reduce the thickness of the first organic compound layer 16a at the side surfaces S₁ and S₃ to a similar extent, effectively reducing leakage current between adjacent pixels.

In addition, in a case where the first electrode 14 is made of indium tin oxide (ITO), a silicon oxide film (SiOₓ) as the first insulating layer 15a is employed. It is known that a silicon nitride film (SiNₓ) employed as the first insulating layer 15a makes the surface of the first insulating layer 15a rough, affecting the formation of the second insulating layer 15b and the third insulating layer 15c.

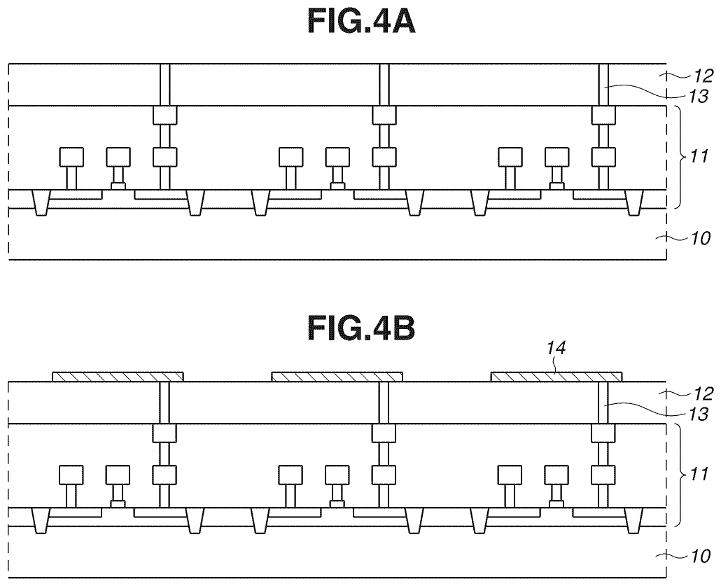

A method of manufacturing the organic light emitting apparatus of FIG. 1 will now be described with reference to FIGS. 4A and 4B, and 5 to 8.

First, as illustrated in FIG. 4A, transistors, capacitors, and the like of drive circuitry including a pixel drive circuit are formed over the substrate 10 by a known Metal Oxide Semiconductor (MOS) process to form the drive circuit layer 11.

Next, an insulating film, such as an oxide film (SiOₓ) or an oxynitride film (SiON), is formed by, for example, a plasma chemical vapor deposition (CVD) method, a high-density plasma method, or a combination thereof, forming the first planarization layer 12. The first planarization layer 12 may be formed by planarizing the surface including the pixel region by a chemical mechanical polishing (CMP) method after the formation of the insulating film.

Next, a plurality of openings is formed at predetermined positions in the first planarization layer 12 by a photolithography method and a dry etching method. For example, tungsten (W) is disposed in each opening, and the excess portion is removed by a CMP method or an etch-back method, forming conductive plugs 13 each made of a conductive material (tungsten).

Next, as illustrated in FIG. 4B, a stacked metal film made of titanium (Ti), titanium nitride (TiN), an aluminum alloy, and titanium (Ti) is formed over the first planarization layer 12 by, for example, a sputtering method. Next, the stacked metal film is patterned into a predetermined shape by a photolithography method and a dry etching method or a wet etching method, and a plurality of first electrodes 14 connected to the conductive plugs 13 is formed in the display region.

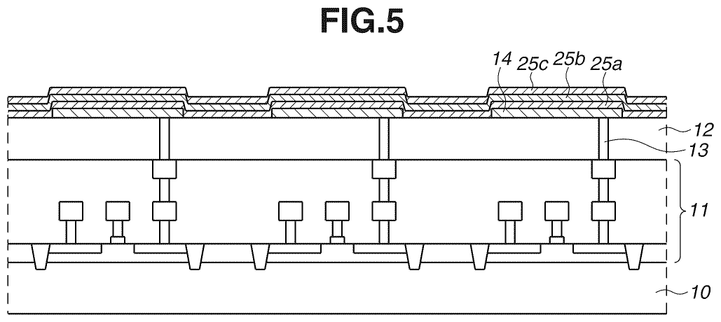

Next, as illustrated in FIG. 5, a first insulating film 25a, a second insulating film 25b, and a third insulating film 25c are stacked over the first electrodes 14 using an insulating material, such as an oxide film (SiOₓ) or a nitride film (SINₓ), by a plasma CVD method. The thickness of each insulating layer can be, for example, one nm to 500 nm.

The method of forming the first insulating film 25a, the second insulating film 25b, and the third insulating film 25c is not limited to the above-mentioned method, and a known method of forming an insulating layer can be optionally applied. For example, to form those films, a manufacturing method other than the above-mentioned method may be selected from among a high-density plasma CVD method, an atomic layer deposition (ALD) method, a sputtering method, and the like, and a coating material may be selected from among a spin coating method, a slit coating method, and the like.

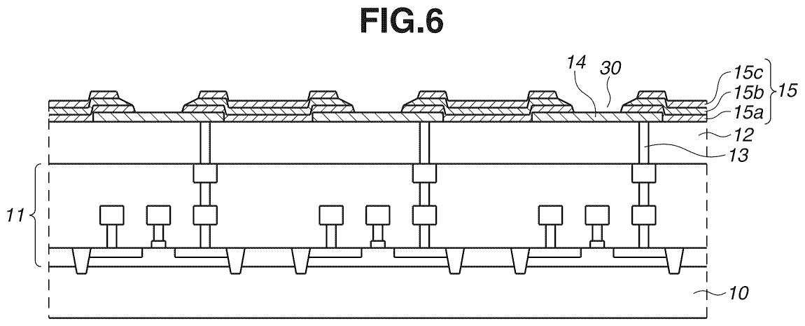

Next, the third insulating film 25c, the second insulating film 25b, and the first insulating film 25a are patterned into predetermined shapes by a photolithography method and a dry etching method, forming the aperture 30 corresponding to each first electrode 14. As a result, as illustrated in FIG. 6, the insulating layer 15 including the first insulating layer 15a, the second insulating layer 15b, and the third insulating layer 15c is formed. At this time, the process is performed by a dry etching method so as to satisfy the above-described relationship of θ₁>θ₂ and θ₃>θ₂.

At the same time, an opening or openings for connecting the second electrode 17 formed in a subsequent step to a metal layer in the same layer as the first electrode 14 is or are also formed (not illustrated).

Next, cleaning is performed to remove foreign matter on the substrate (the first electrode 14 and the insulating layer 15) before the organic compound layer 16 is formed in the next operation. After the cleaning process, a dehydration process is performed to remove moisture from the surface of the substrate.

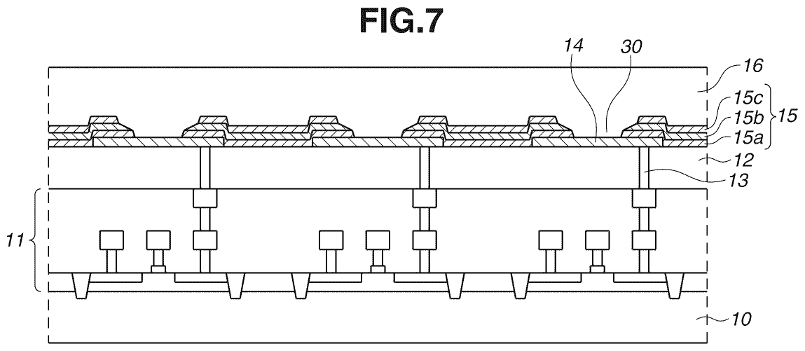

Subsequently, as illustrated in FIG. 7, an organic layer having lower resistance than the light emitting layer, such as a hole injection layer and a hole transport layer, a light emitting layer, and an electron transport layer are sequentially deposited as organic materials included in the organic EL element by, for example, a vacuum deposition method, forming the organic compound layer 16. As the vacuum deposition method, for example, a rotary deposition method, an in-line deposition method, or a transfer deposition method can be employed. The organic compound layer 16 may be a hole injection layer, a hole transport layer, a light emitting layer, a charge generation layer, a light emitting layer, or an electron transport layer.

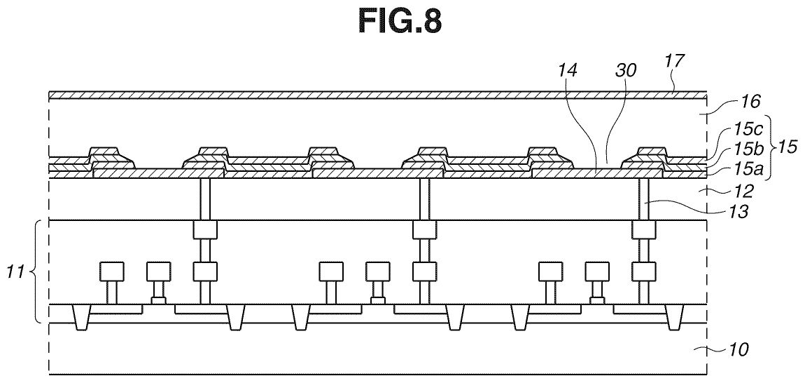

Next, as illustrated in FIG. 8, the second electrode 17 is formed by a vacuum deposition method, subsequently without releasing the substrate from the reduced pressure atmosphere to the atmosphere.

Further, a moisture-proof layer 18, a second planarization layer 19, and a color filter layer 20 are formed to cover the second electrode 17 by, for example, a plasma CVD method, a sputtering method, an ALD method, or a combination thereof, producing the organic light emitting apparatus illustrated in FIG. 1. It is favorable for the film formation temperature of the moisture-proof layer 18 to be equal to or lower than the decomposition temperature of the organic material constituting the organic compound layer 16, for example, 120° C. or lower. In addition, in the color filter layer 20, for example, a material of a red filter is applied onto the second planarization layer 19, and is subjected to patterning performed by photolithography, forming the red filter, and subsequently, a green filter and a blue filter are sequentially formed in a similar manner to the red filter. The second planarization layer 19 is a transparent member arranged between the color filter layer 20 and the moisture-proof layer 18 as necessary in order to improve the adhesion therebetween.

Finally, a terminal extraction pad portion (not illustrated) in the display apparatus is formed by patterning into a predetermined shape by a photolithography method and a dry etching method.

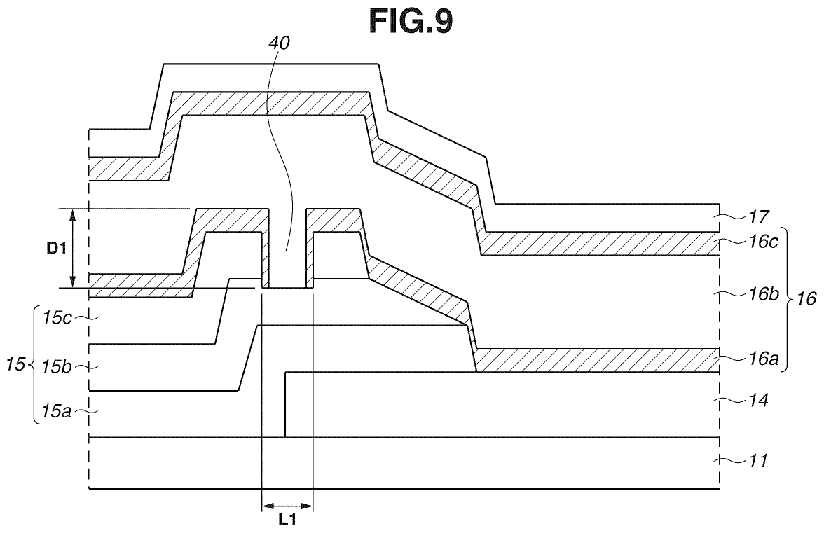

In the present embodiment, as illustrated in FIG. 9, it is favorable for the third insulating layer 15c to have a groove 40 surrounding the aperture 30 of the insulating layer 15 over the first electrode 14 in a plan view with respect to the lower surface of the first electrode 14. The second insulating layer 15b is exposed in the groove 40, and the first organic compound layer 16a disposed over the groove 40 has a locally thin portion or a discontinuous portion in the groove 40. In the form of FIG. 9, the first organic compound layer 16a is discontinuous at the bottom of the groove 40. As described above, the first organic compound layer 16a is locally thin or has a discontinuous portion, thus increasing the resistance of the first organic compound layer 16a. This allows reduction or prevents leakage current that propagates from the first electrode 14 through the first organic compound layer 16a and flows between adjacent pixels.

In order to increase the resistance of the first organic compound layer 16a to reduce leakage current, it is favorable for the aspect ratio of the groove 40 to be 0.3 or more, and it is more favorable to be 1.0 or more. The aspect ratio of the groove 40 refers to a ratio (L1/D1) of a depth D1 of the groove 40 in a stacked layer direction to a length L1 (width) of the groove 40 in a direction orthogonal to the stacked layer direction. As described below, in a case where the second insulating layer 15b is used as an etching stopper film in forming the groove 40, the depth D1 of the groove 40 corresponds to the thickness of the second insulating layer 15b.

It is favorable for the length L1 of the groove 40 to be larger than the thickness of the first organic compound layer 16a, allowing the first organic compound layer 16a to be locally thin or discontinuous.

When the groove 40 is processed by dry etching, in the present embodiment, the second insulating layer 15b can be used as an etching stopper film. As described above, in the case where the etching rate of the second insulating layer 15b is lower than the etching rate of the third insulating layer 15c, the process under the same dry etching conditions enables the relationship that θ₃ is larger than θ₂. Such a combination of insulating layers having different etching rates allows the second insulating layer 15b to be used as an etching stopper film in forming the groove 40, reducing the variation in the depth of the groove 40.

The first organic compound layer 16a may include an organic light emitting layer and a charge generation layer, in addition to at least one of the hole injection layer and the hole transport layer. With θ₁ and θ₃ being large and the side surfaces S₁ and S₃ being steep, the charge generation layer can be made thin, and also at the groove 40. This can increase the resistance of the charge generation layer while the charge generation layer has low resistance like the hole injection layer and the hole transport layer, whereby leakage current between adjacent pixels can be reduced.

A procedure of a method of manufacturing the organic light emitting apparatus of FIG. 9 will be described. First, as illustrated in FIG. 5, the first insulating film 25a, the second insulating film 25b, and the third insulating film 25c are formed over the first electrodes 14 using the insulating material, such as an oxide film (SiOₓ) or a nitride film (SiNₓ), by the plasma CVD method as in the organic light emitting apparatus illustrated in FIG. 1.

Next, the third insulating film 25c, the second insulating film 25b, and the first insulating film 25a are patterned into predetermined shapes by the photolithography method and the dry etching method to form the aperture 30 corresponding to each first electrode 14. This, as illustrated in FIG. 6, forms the insulating layer 15 including the first insulating layer 15a, the second insulating layer 15b, and the third insulating layer 15c.

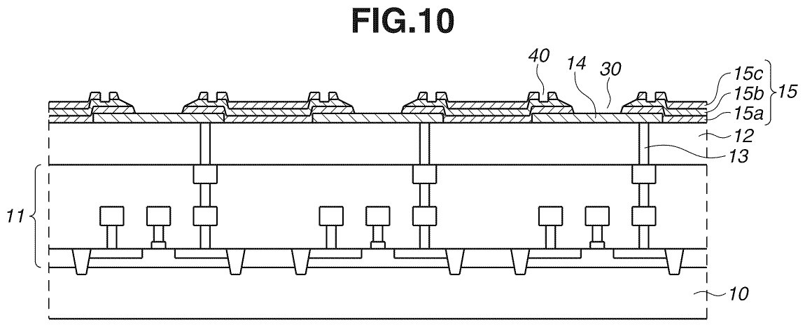

Next, as illustrated in FIG. 10, the third insulating layer 15c is patterned into a predetermined shape by a photolithography method and a dry etching method to form the groove 40. At this time, the second insulating layer 15b made of the material different from that of the third insulating layer 15c can be used as the etching stopper film. In a case where a fluorocarbon-based gas without hydrogen is used as the dry etching gas, an oxide film (SiOₓ) as the third insulating layer 15c and a nitride film (SiNₓ) as the second insulating layer 15b are employed.

The etching process of forming the groove 40 in the third insulating layer 15c may overlap, at least in part, with the etching process of the third insulating film 25c.

Subsequent steps are the same as those of the method of manufacturing the organic light emitting apparatus of FIG. 1.

### <Configuration of Organic Light Emitting Apparatus>

Hereinafter, other configurations of the organic light emitting apparatus of the present embodiment will be described. As illustrated in FIG. 1, the organic light emitting apparatus typically includes an organic EL element composed of a first electrode 14, the organic compound layer 16, and the second electrode 17, and the organic compound layer 16 includes at least a light emitting layer. The organic light emitting apparatus further includes the substrate 10 and the first planarization layer 12, and the moisture-proof layer 18, the second planarization layer 19, and a color filter layer 20 may be provided over the second electrode 17, and a not-illustrated microlens or the like may be provided. A third planarization layer may be provided between the color filter layer 20 and the microlens (not illustrated).

Hereinafter, configurations of the organic light emitting apparatus of the present embodiment and an apparatus including the organic light emitting apparatus will be described.

### [Substrate]

Examples of the substrate 10 include quartz, glass, a silicon wafer, a resin, and a metal. As illustrated in FIG. 1, the drive circuit layer 11 including a switching device, such as a transistor, and wiring is provided over the substrate 10, and the first planarization layer 12 is provided over the drive circuit layer 11. The first planarization layer 12 may be made of any material as long as a conductive plug 13 can be formed and the electrical insulation from wiring not connected can be ensured. For example, a resin, such as polyimide, silicon oxide, silicon nitride, or the like can be employed.

### [Electrode]

When an electric field is applied in the direction in which the organic light emitting apparatus emits light, between the first electrode 14 and the second electrode 17, one electrode having a higher potential corresponds to the anode, and the other electrode corresponds to the cathode. In addition, it can also be said that the electrode which supplies holes to the light emitting layer corresponds to the anode and the electrode which supplies electrons corresponds to the cathode. In the present embodiment, either the anode or the cathode may be the first electrode 14.

### [Organic Compound Layer]

While the organic compound layer 16 is composed of the hole transport layer, the light emitting layer, and the electron transport layer as an example, any one of a multilayer film or a single-layer film can be stacked, each of which includes a plurality of functional layers, such as a hole injection layer and an electron injection layer for facilitating supply of holes and electrons to the light emitting layer, a hole blocking layer and an electron blocking layer for preventing excessive movement of holes and electrons, and a buffer layer for adjusting movement of holes and electrons from the electrodes.

The organic compound layer 16 is formed as a layer common to a plurality of sub-pixels and a plurality of pixels. The common layer is arranged across a plurality of pixels.

The organic compound layer 16 can be formed by a dry process, such as a vacuum deposition, ionization deposition, sputtering, or plasma deposition. Instead of the dry process, a wet process may be employed in which the organic compound layer 16 is formed by a known coating method (for example, spin coating, dipping, a casting method, a Langmuir-Blodgett (LB) method, or an inkjet method) using the solution prepared by dissolving the compound in an appropriate solvent.

Here, the organic compound layer 16 formed by a vacuum deposition method, a solution coating method, or the like is less likely to undergo crystallization or the like, providing excellent temporal stability. In forming a film by a coating method, the film can be formed in combination with an appropriate binder resin.

Examples of the binder resin include, but are not limited to, a polyvinyl carbazole resin, a polycarbonate resin, a polyester resin, an acrylonitrile butadiene styrene (ABS) resin, an acrylic resin, a polyimide resin, a phenol resin, an epoxy resin, a silicone resin, and a urea resin.

Any of those binder resins may be used alone as a homopolymer or a copolymer, or two or more kinds of those binder resins may be used in combination. Further, if necessary, additives, such as a known plasticizer, antioxidant, and ultraviolet absorber, may be used in combination.

### [Moisture-Proof Layer]

As the moisture-proof layer 18, glass provided with a moisture absorbent is bonded to the second electrode 17, reducing the entry of water or the like into the organic compound layer 16, resulting in reduced occurrences of display defects. In another embodiment, a passivation film of silicon nitride or the like may be provided over the second electrode 17 to reduce the entry of water or the like into the organic compound layer 16. For example, after the second electrode 17 is formed and then the element is transferred to another chamber without breaking the vacuum, a silicon nitride film having a thickness of two micrometers (μm) may be formed by a CVD method, producing the moisture-proof layer 18. After the film formation by the CVD method, the moisture-proof layer 18 may be provided by an atomic layer deposition method (ALD method). The material of the film formed by the ALD method is not limited, and may be silicon nitride, silicon oxide, aluminum oxide, or the like. Over the film formed by the ALD method, silicon nitride may be further formed by a CVD method. The film formed by the ALD method may have a smaller thickness than the film formed by the CVD method. Specifically, the thickness of the film formed by the ALD method may be 50% or less, and further 10% or less smaller than that of the film formed by the CVD method.

### [Second Planarization Layer]

The second planarization layer 19 may be provided between a color filter layer 20 and the moisture-proof layer 18. The second planarization layer 19 is provided for the purpose of reducing unevenness of the lower layer. Without limiting the purpose, the second planarization layer 19 may be referred to as a material resin layer. The second planarization layer 19 may be formed of an organic compound, whether the organic compound is a low-molecular-weight compound or a high-molecular-weight compound, but it is favorable for the organic compound to be a high-molecular-weight compound.

The second planarization layer 19 may be provided over and below the color filter layer 20, and the materials thereof may be the same or different. Specifically, examples of the materials include a polyvinyl carbazole resin, a polycarbonate resin, a polyester resin, an ABS resin, an acrylic resin, a polyimide resin, a phenol resin, an epoxy resin, a silicone resin, and a urea resin.

### [Color Filter Layer]

The color filter layer 20 can be formed over the moisture-proof layer 18 or over the second planarization layer 19 provided over the moisture-proof layer 18. Further, another substrate on which a color filter in consideration of the size of the organic light emitting apparatus is provided may be bonded to the substrate provided with the organic light emitting apparatus, and the color filter may be formed using a high-molecular-weight compound.

### [Microlens]

The organic light emitting apparatus may include an optical member, such as a microlens, on the light emission side of the organic light emitting apparatus. The microlens can be formed of an acrylic resin, an epoxy resin, or the like. The microlens may be used to increase the quantity of light taken from the organic light emitting apparatus or to control the direction of the light taken. The microlens may have a hemispherical shape. With the microlens formed in a hemispherical shape, of the tangents in contact with the hemisphere, there is a tangent parallel to an insulating layer, and the point of contact between the tangent and the hemisphere is the vertex of the microlens. The vertex of the microlens can be determined in a desired cross sectional view in a similar way. That is, of the tangents in contact with the semicircle of the microlens in a cross sectional view, there is a tangent that is parallel to the insulating layer, and the point of contact between the tangent and the semicircle is the vertex of the microlens.

The midpoint of the microlens can also be defined. In a cross section of the microlens, on the assumption of a line segment from one endpoint where the shape of the arc starts to the other endpoint where the shape of the arc ends, the midpoint of the line segment can be referred to as the midpoint of the microlens. The cross section for determining the vertex and the midpoint may be a cross section perpendicular to the insulating layer.

### [Opposing Substrate]

An opposing substrate may be provided over the color filter layer 20 or a planarization layer over the color filter layer 20. The opposing substrate is provided at a position corresponding to the substrate 10 described above, and thus is referred to as an opposing substrate. The material of the opposing substrate may be the same as that of the substrate 10.

### [Drive Circuit Layer]

The organic light emitting apparatus includes the drive circuit layer 11. The drive circuit layer 11 may be used for an active matrix display apparatus that controls light emission of a plurality of organic EL elements independently. The active matrix circuit may be driven by controlling a voltage or current. The drive circuit layer 11 includes a transistor that drives the organic EL element, and includes a pixel circuit for each pixel. Specifically, the pixel circuit includes a transistor that controls the luminance of light emitted from the organic EL element. The pixel circuit may include one or more of a transistor for controlling the timing of light emission, a capacitor for holding the gate voltage of a transistor for controlling the luminance of light emitted, and a transistor for connecting to ground without passing through the light emitting element.

The organic light emitting apparatus includes a display region and a peripheral region disposed around the display region. The display region includes a pixel circuit, and the peripheral region includes a display control circuit. The mobility of the transistor included in the pixel circuit may be lower than the mobility of the transistor included in the display control circuit. The slope of the current-voltage characteristics of the transistor included in the pixel circuit may be smaller than the slope of the current-voltage characteristics of the transistor included in the display control circuit. The slope of the current-voltage characteristics can be measured by the so-called Vg-Ig characteristics. The transistor included in the pixel circuit is a transistor connected to the organic EL element.

### [Pixel]

The organic light emitting apparatus may include a plurality of pixels. Each pixel includes sub-pixels that emit light of different colors from each other. The sub-pixels may emit, for example, red, green, and blue (RGB) colors.

In a pixel, light is emitted from an area also referred to as a pixel aperture. The pixel aperture may be 15 μm or less, and may be 5 μm or more. More specifically, the pixel aperture may be 11 μm, 9.5 μm, 7.4 μm, 6.4 μm, or the like. The distance between the sub-pixels may be 10 μm or less, and specifically, may be 8 μm, 7.4 μm, or 6.4 μm.

The pixels may be arranged in a known configuration in a plan view. Examples of the known configuration may include a stripe arrangement, a delta arrangement, a pentile arrangement, and a Bayer arrangement. The shape of a sub-pixel in a plan view may be any known shape. Examples of the shape include a rectangle, a quadrangle, such as a rhombus, and a hexagon. Of course, any shape that is not an exact figure but is close to a rectangle is included in rectangles. A shape of sub-pixels and a pixel arrangement can be used in combination.

### <Applications of Organic Light Emitting Apparatus>

The organic light emitting apparatus of the present embodiment can be used as a constituent member of a display apparatus or a lighting apparatus. In addition, the organic light emitting apparatus is used as an exposure light source of an electrophotographic image forming apparatus, a backlight of a liquid crystal display apparatus, a light emitting apparatus including a color filter in a white light source, or the like.

The display apparatus may be an image information processing apparatus that includes an image input unit into which image information is input from an area charge-coupled device (CCD), a linear CCD, a memory card, or the like, and an information processing unit that performs processing on the input information, and that displays the input image on a display unit. The display apparatus may include a plurality of pixels, at least one of which includes the organic light emitting apparatus according to the present embodiment and a transistor connected to the organic light emitting apparatus.

A display unit included in an imaging device or an ink jet printer may have a touch panel function. The driving method for the touch panel function may be an infrared method, a capacitive method, a resistive film method, or an electromagnetic induction method, and is not particularly limited. The display apparatus may be employed in a display unit of a multifunction peripheral.

The display apparatus according to the present embodiment will now be described with reference to drawings.

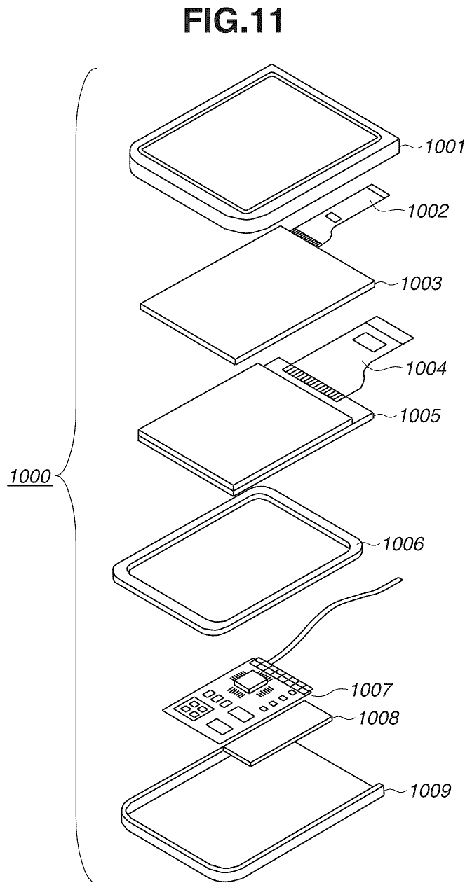

FIG. 11 is a schematic view illustrating an example of the display apparatus according to the present embodiment. A display apparatus 1000 includes a touch panel 1003, a display panel 1005, a frame 1006, a circuit board 1007, and a battery 1008 between an upper cover 1001 and a lower cover 1009. Flexible printed circuit (FPC) boards 1002 and 1004 are connected to the touch panel 1003 and the display panel 1005, respectively. The circuit board 1007 has transistors printed thereon. The battery 1008 may not be provided unless the display apparatus is a portable device, and may be provided in another position even if the display apparatus is a portable device.

The display apparatus according to the present embodiment may include color filters having red, green, and blue colors, respectively. The color filters may be arranged in a delta arrangement of the red, green, and blue colors.

The display apparatus according to the present embodiment is used in a display unit of a mobile terminal. In that case, the display apparatus may have both a display function and an operation function. Examples of the mobile terminal include a mobile phone, such as a smartphone, a tablet, and a head-mounted display.

The display apparatus according to the present embodiment is used in a display unit of an imaging device including an optical unit including a plurality of lenses and an image sensor that receives light that passes through the optical unit. The imaging device may include a display unit that displays information acquired by the image sensor. The display unit may be exposed to the outside of the imaging device or arranged in a viewfinder. The imaging device may be a digital camera or a digital video camera.

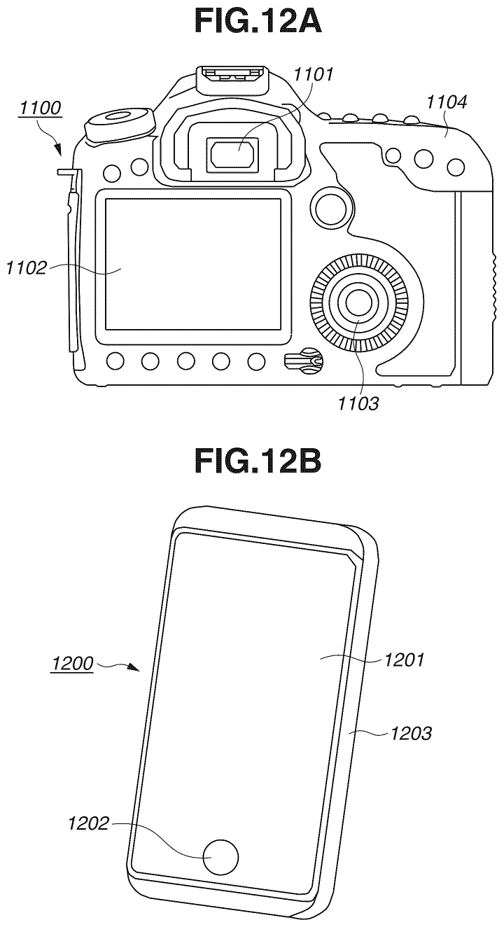

FIG. 12A is a schematic view illustrating an example of the imaging device according to the present embodiment. An imaging device 1100 includes a viewfinder 1101, a rear display 1102, an operation unit 1103, and a housing 1104. The viewfinder 1101 includes the display apparatus according to the present embodiment. In this case, the display apparatus may display an image to be captured and also environmental information, an imaging instruction, and the like. The environmental information may be the intensity of ambient light, the direction of ambient light, the moving speed of a subject, the possibility that the subject will be shielded by a shielding object, or the like.

The period suitable for imaging is short time, so that it is better to display information as soon as possible. Thus, it is favorable for the display apparatus using the organic light emitting apparatus according to the present embodiment to be used. This is because the organic light emitting apparatus has high-speed response. The display apparatus using the organic light emitting apparatus can be used more suitably than a display apparatus using a liquid crystal display device for those devices which require high-speed display.

The imaging device 1100 includes a not-illustrated optical unit. The optical unit includes a plurality of lenses, and forms an image on an image sensor housed in the housing 1104. The plurality of lenses can adjust the focal point by adjusting relative positions thereof. This operation can be performed automatically. The imaging device may also be referred to as a photoelectric conversion apparatus. The photoelectric conversion apparatus does not only sequentially capture images, but also can use, as an image capturing method, a method of detecting a difference from a previous image, a method of cutting out an image that is recorded at all times, and the like.

FIG. 12B is a schematic view illustrating an example of an electronic apparatus according to the present embodiment. An electronic apparatus 1200 includes a display portion 1201, an operation portion 1202, and a housing 1203. The housing 1203 may include circuitry, a printed circuit board including the circuitry, a battery, and a communication portion. The operation portion 1202 may be a button or a touch panel type reaction portion. The operation portion 1202 may be a biometric recognition portion that determines a fingerprint and then performs unlocking or the like. An electronic apparatus including a communication unit can also be referred to as a communication apparatus. The electronic apparatus 1200 may further have a camera function by including a lens and an image sensor. An image captured by the camera function is displayed on the display portion. Examples of the electronic apparatus 1200 include a smartphone and a laptop computer.

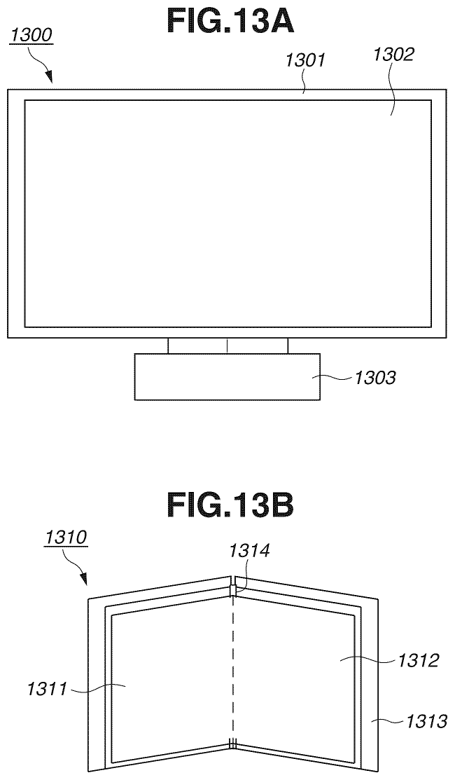

FIGS. 13A and 13B are schematic views illustrating an example of a display apparatus according to the present embodiment. FIG. 13A illustrates a display apparatus, such as a television monitor or a personal computer (PC) monitor. A display apparatus 1300 includes a frame 1301 and a display portion 1302. The organic light emitting apparatus according to the present embodiment are used in the display portion 1302. The display apparatus 1300 includes the frame 1301 and a base 1303 supporting the display portion 1302. The base 1303 is not limited to the form of FIG. 13A. The lower side of the frame 1301 may also serve as a base. The frame 1301 and the display portion 1302 may be bent. The radius of curvature may be equal to or larger than 5,000 millimeters (mm) and equal to or smaller than 6,000 mm.

FIG. 13B is a schematic view illustrating another example of a display apparatus according to the present embodiment. A display device 1310 of FIG. 13B is configured to be foldable, a so-called foldable display device. The display device 1310 includes a first display portion 1311, a second display portion 1312, a housing 1313, and a bending point 1314. The first display portion 1311 and the second display portion 1312 include the organic light emitting apparatus according to the present embodiment. The first display portion 1311 and the second display portion 1312 may be a single display device without a joint. The first display portion 1311 and the second display portion 1312 can be separated from each other at the bending point 1314. The first display portion 1311 and the second display portion 1312 may display different images, or the first and second display units may display one image.

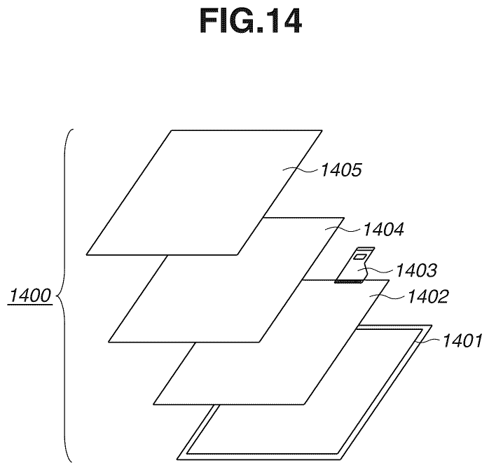

FIG. 14 is a schematic view illustrating an example of a lighting apparatus according to the present embodiment. A lighting apparatus 1400 includes a housing 1401, a light source 1402, a circuit board 1403, an optical filter 1404, and a light diffusion portion 1405. The light source 1402 includes the organic light emitting apparatus according to the present embodiment. The optical filter 1404 may be a filter that improves the color rendering property of the light source. The light diffusion portion 1405 can effectively diffuse the light of the light source 1402 and deliver the light to a wide range, such as display lighting. The optical filter 1404 and the light diffusion portion 1405 may be provided on the light emission side of the lighting. A cover may be provided on the outermost portion as necessary.

The lighting apparatus is, for example, an apparatus that illuminates the inside of a room. The lighting apparatus may emit white light, neutral white light, or any other color light from blue to red. A dimming circuit for dimming the light may be provided. The lighting apparatus includes the organic light emitting apparatus according to the present embodiment and a power supply circuit connected thereto. The power supply circuit is a circuit that converts alternating current (AC) voltages into direct current (DC) voltages. As color temperatures, white corresponds to 4,200 K, and neutral white corresponds to 5,000 K. The lighting apparatus may include a color filter.

The lighting apparatus according to the present embodiment may include a heat dissipation portion. The heat dissipation portion is used for dissipating heat inside the apparatus to the outside of the apparatus, and examples thereof include a metal having a high specific heat and liquid silicone.

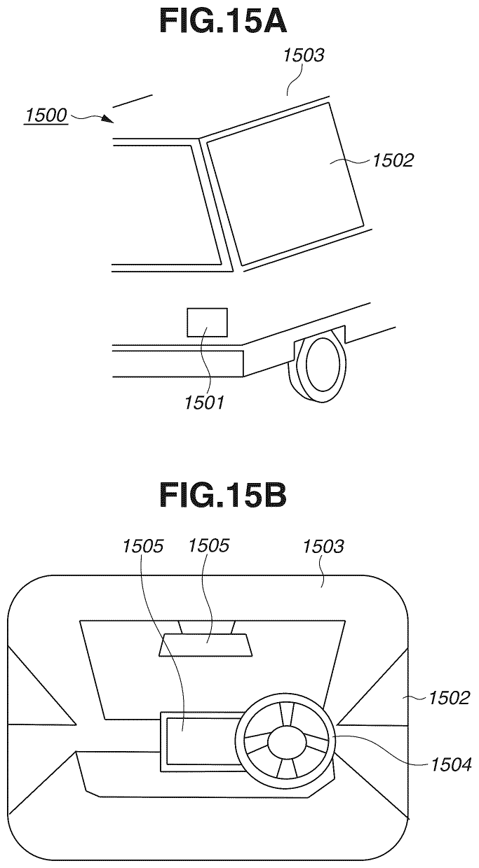

FIG. 15A is a schematic diagram of an automobile as an example of a moving object according to the present embodiment. As illustrated in FIG. 15A, an automobile 1500 includes a tail lamp 1501 as an example of a lamp. The automobile 1500 may include the tail lamp 1501 that is turned on when a brake operation or the like is performed.

The tail lamp 1501 includes the organic light emitting apparatus according to the present embodiment. The tail lamp 1501 may include a protective member that protects each of the organic light emitting apparatus. The protective member may be made of any material as long as the material has a certain degree of high strength and is transparent, but the material may be made of polycarbonate or the like. A furandicarboxylic acid derivative, an acrylonitrile derivative, or the like may be mixed with the polycarbonate.

The automobile 1500 may include an automobile body 1503, a window 1502 attached to the automobile body 1503. The window 1502 may be a transparent display as long as the window is not used for checking areas ahead of and behind the automobile. The transparent display includes the organic light emitting apparatus according to the present embodiment. In this case, the constituent material(s) of the electrode(s) and the like included in each organic light emitting apparatus is or are formed of transparent members.

As illustrated in FIG. 15B, the automobile 1500 includes a steering wheel 1504 for controlling the moving direction of the moving object and a display unit 1505 mounted on the automobile body 1503 that displays a map, the position of the moving object, a turning direction, and the like. The display unit 1505 includes the organic light emitting apparatus according to the present embodiment.

While an example in which the moving object is an automobile is described here, the moving object according to the present embodiment may be a ship, an aircraft, a drone, or the like. The moving object includes an airframe, and a lamp and a display unit provided on the airframe. The lamp emits light for notifying the position of the airframe. Either the lamp or the display unit includes the organic light emitting apparatus according to the present embodiment.

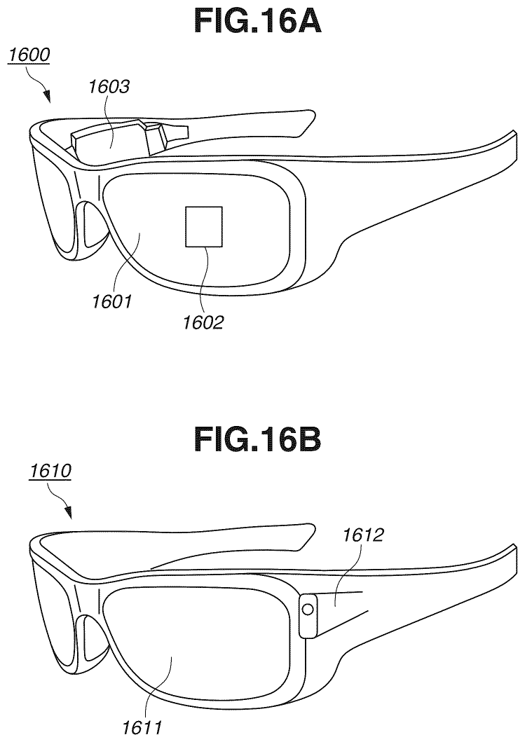

An application example of the display apparatus of each of the embodiments described above will be described with reference to FIGS. 16A and 16B. The display apparatus is applicable to a system that can be worn as a wearable device, such as smart glasses, a head mounted display (HMD), or a smart contact. An imaging display apparatus used in such an application example includes an imaging device capable of photoelectrically converting visible light and a display apparatus capable of emitting visible light.

FIG. 16A is a schematic view of a pair of spectacles 1600 (smart glasses) according to one application example. An imaging device 1602, such as a complementary metal-oxide semiconductor (CMOS) sensor or a single photon avalanche diode (SPAD), is disposed on the front surface side of a lens 1601 of the pair of spectacles 1600. The display apparatus according to any of the above-described embodiments is provided on the back surface side of the lens 1601.

The pair of spectacles 1600 further includes a control device 1603. The control device 1603 functions as a power supply that supplies power to the imaging device 1602 and the display apparatus according to each embodiment. The control device 1603 controls the operations of the imaging device 1602 and the display apparatus. The lens 1601 includes an optical system for focusing light on the imaging device 1602.

FIG. 16B illustrates a pair of spectacles 1610 (smart glasses) according to one application example. The pair of spectacles 1610 include a control device 1612, and an imaging device corresponding to the imaging device 1602 in FIG. 16A and a display apparatus are mounted on the control device 1612. An optical system for projecting light emitted from the imaging device and the display apparatus in the control device 1612 is formed in the lens 1611 on which an image is projected. The control device 1612 functions as a power supply that supplies power to the imaging device and the display apparatus, and controls the operations of the imaging device and the display apparatus. The control device 1612 may include a line-of-sight detection unit that detects a line-of-sight of the wearer. Infrared rays may be used for the detection of the line of sight. An infrared light emitting unit emits infrared light to the eyeball of the user who is gazing at an image being displayed. An imaging unit including a light receiving element detects reflected light of the emitted infrared light from the eyeball, obtaining a captured image of the eyeball. By providing reduction means configured to reduce light from the infrared light emitting unit to a display portion in a plan view, the deterioration of image quality is reduced.

The line-of-sight of the user with respect to the image being displayed is detected from the captured image of the eyeball obtained by image capturing using infrared light. Any known method can be applied to the line-of-sight detection using the captured image of the eyeball. As an example, a line-of-sight detection method based on a Purkinje image by reflection of irradiation light on the cornea can be used. More specifically, line-of-sight detection processing based on a pupil-corneal reflection method is performed. A line-of-sight vector representing the orientation (rotation angle) of the eyeball is calculated based on the image of the pupil and the Purkinje image included in the captured image of the eyeball using the pupil-corneal reflection method, and thus the line of sight of the user is detected.

The display apparatus according to the present embodiment may include an imaging device including a light receiving element, and control an image being displayed on the display apparatus based on line-of-sight information about the user from the imaging device. Specifically, the display apparatus determines a first field-of-view region at which the user gazes and a second field-of-view region other than the first field-of-view region based on line-of-sight information. The first field-of-view region and the second field-of-view region may be determined by the control device of the display apparatus, or the first field-of-view region and the second field-of-view region determined by an external control device may be received. In the display region of the display apparatus, the display resolution of the first field-of-view region may be controlled to be higher than the display resolution of the second field-of-view region. That is, the resolution of the second field of view region may be lower than that of the first field of view region.

The display region includes a first display region and a second display region different from the first display region, and a region having a higher priority is determined between the first display region and the second display region based on line-of-sight information. The first display region and the second display region may be determined by the control device of the display apparatus, or the first display region and the second display determined by an external control device may be received. The resolution of the region with a high priority may be controlled to be higher than the resolution of the region other than the region with a high priority. That is, the resolution of a region with a relatively low priority may be lowered.

Artificial intelligence (AI) may be employed to determine the first display region and the region with a high priority. The AI may be a model configured to estimate an angle of a line of sight and a distance to a target object lying in the line of sight from an image of an eyeball using images of eyeballs and directions in which the eyeball of the images actually views as teaching data. The AI program(s) may be included in the display apparatus, the imaging device, or an external device. If the external device includes the AI program(s), the AI program(s) is or are transmitted to the display apparatus via communication.

In the case of performing display control based on visual recognition detection, the light emitting device according to the present embodiment can be favorably applied to smart glasses further including an imaging device that captures images of the outside. The smart glasses can display captured external information in real time.

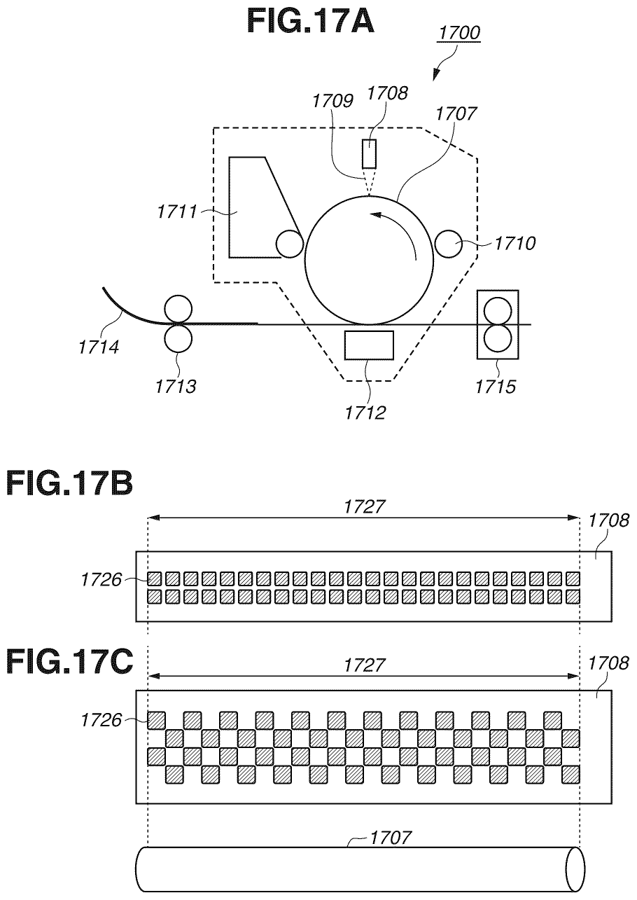

FIG. 17A is a schematic view illustrating an example of an image forming apparatus according to the present embodiment. An image forming apparatus 1700, an electrophotographic image forming apparatus, includes a photosensitive member 1707, an exposure light source 1708, a charging unit 1710, a developing unit 1711, a transfer unit 1712, a conveyance roller 1713, and a fixing unit 1715. Light 1709 is emitted from the exposure light source 1708, and forms an electrostatic latent image on the surface of the photosensitive member 1707. The exposure light source 1708 includes the organic light emitting apparatus according to the present embodiment. The developing unit 1711 includes toner and the like. The charging unit 1710 charges the photosensitive member 1707.

The transfer unit 1712 transfers a developed image to a recording medium 1714. The conveyance roller 1713 conveys the recording medium 1714. The recording medium 1714 is, for example, paper. The fixing unit 1715 fixes the image formed on the recording medium 1714.

FIGS. 17B and 17C are each a diagram illustrating the exposure light source 1708, and are schematic views illustrating arrangements of a plurality of light emitting units 1726 on a long substrate. Arrows 1727 are directions parallel to the axis of the photoreceptive member 1707 and represents the row directions in which the organic light emitting apparatus is arranged. One of the row directions is the same as the direction of the axis about which the photosensitive member 1707 rotates. This direction can also be referred to as the long-axis direction of the photosensitive member 1707. FIG. 17B illustrates a form in which the light emitting units 1726 are arranged in the long-axis direction of the photosensitive member 1707. The light emitting units 1726 each include the organic light emitting apparatus according to the present embodiment.

FIG. 17C illustrates a form different from that of FIG. 17B, in which the light emitting units 1726 are alternately arranged in the column directions in each of the first column and the second column. The first column and the second column are arranged at different positions in a row direction. In the first column, the plurality of light emitting units 1726 is arranged at intervals. In the second column, the light emitting units 1726 are arranged at positions corresponding to the intervals between the light emitting units 1726 in the first column. That is, the plurality of light emitting units 1726 is also arranged at intervals in the row direction. The arrangement of FIG. 17C can be rephrased as, for example, a state of being arranged in a lattice configuration, a state of being arranged in a houndstooth check, or an alternating grid pattern.

As described above, the use of the organic light emitting apparatus according to the present embodiment enables stable display with favorable image quality even for long-term display.

According to the present disclosure, an organic light emitting apparatus is provided which reduces leakage current between adjacent pixels and which has higher light emitting characteristics.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-135200, filed Aug. 14, 2024, which is hereby incorporated by reference herein in its entirety.

What is claimed is:

1. An organic light emitting apparatus comprising:
a substrate;
a first electrode disposed over the substrate;
an insulating layer disposed over the substrate, the insulating layer having an aperture over the first electrode and covering an outer periphery of the first electrode;
an organic compound layer covering the first electrode and the insulating layer; and
a second electrode disposed over the organic compound layer,
wherein the insulating layer includes a first insulating layer, a second insulating layer, and a third insulating layer in that order from the substrate side,
wherein the second insulating layer is different in material from both the first insulating layer and the third insulating layer,
wherein, a side surface S₁ of the first insulating layer, a side surface S₂ of the second insulating layer, and a side surface S₃ of the third insulating layer are all in contact with the organic compound layer, the side surfaces S₁, S₂, and S₃ surrounding the aperture, and
wherein an angle θ₁ of the side surface S₁ of the first insulating layer with respect to a lower surface of the first electrode and an angle θ₃ of the side surface S₃ of the third insulating layer with respect to the lower surface of the first electrode are both larger than an angle θ₂ of the side surface S₂ of the second insulating layer with respect to the lower surface of the first electrode.

2. The organic light emitting apparatus according to claim 1, wherein the angle θ₁ is larger than 50° and smaller than 90°.

3. The organic light emitting apparatus according to claim 1, wherein the angle θ₂ is larger than 0° and smaller than or equal to 50°.

4. The organic light emitting apparatus according to claim 1, wherein the angle θ₃ is larger than 50° and smaller than 90°.

5. The organic light emitting apparatus according to claim 1, wherein the first insulating layer and the third insulating layer comprise the same material.

6. The organic light emitting apparatus according to claim 5, wherein the first insulating layer and the third insulating layer comprise silicon oxide, and the second insulating layer has silicon nitride.

7. The organic light emitting apparatus according to claim 1, wherein the third insulating layer has a groove surrounding the aperture in a plan view of the lower surface of the first electrode, and the second insulating layer is exposed in the groove.

8. The organic light emitting apparatus according to claim 1, wherein, in a case where etching is performed using a fluorocarbon gas containing no hydrogen, an etching rate of the first insulating layer is higher than an etching rate of the second insulating layer, and an etching rate of the third insulating layer is higher than the etching rate of the second insulating layer.

9. A method of manufacturing an organic light emitting apparatus, the method comprising:
forming a first insulating film, a second insulating film, and a third insulating film in that order over a substrate provided with a first electrode; and
forming a third insulating layer, a second insulating layer, and a first insulating layer by etching the third insulating film, the second insulating film, and the first insulating film, respectively,
wherein the first electrode is exposed in the etching of the first insulating film, and
wherein in the etching of the third insulating film, the second insulating film, and the first insulating film, an etching rate of the second insulating film is lower than an etching rate of the third insulating film.

10. The method according to claim 9, wherein in the etching of the third insulating film, the second insulating film, and the first insulating film, the etching rate of the second insulating film is lower than the etching rate of the first insulating film.

11. The method according to claim 9, wherein in the etching, a fluorocarbon gas containing no hydrogen is used.

12. The method according to claim 9, wherein the first insulating layer is the same in material as the third insulating layer.

13. The method according to claim 12, wherein the first insulating layer and the third insulating layer are made of silicon oxide, and the second insulating layer is made of silicon nitride.

14. The method according to claim 9, further comprising etching including:
forming a groove in the third insulating layer, the groove surrounding the aperture over the first electrode; and
exposing the second insulating layer in the groove.

15. The method according to claim 14, wherein the etching of forming the groove in the third insulating layer is performed at least partially simultaneously with the etching of the third insulating film.

16. The method according to claim 9, wherein in the exposing of the first electrodes, the etching is performed so that an angle θ₂ of a side surface S₂ of the second insulating layer with respect to a lower surface of the first electrode is smaller than an angle θ₁ of a side surface S₁ of the first insulating layer with respect to the lower surface of the first electrode and an angle θ₃ of a side surface S₃ of the third insulating layer with respect to the lower surface of the first electrode.

17. A display apparatus comprising:
a display unit including the organic light emitting apparatus according to claim 1; and
a housing provided with the display unit.

18. A photoelectric conversion apparatus comprising:
a sensor configured to receive light; and
a display unit configured to display an image captured by the sensor,
wherein the display unit includes the organic light emitting apparatus according to claim 1.

19. An electronic apparatus comprising:
a display unit including the organic light emitting apparatus according to claim 1;
a housing provided with the display unit; and
a communication unit included in the housing and configured to communicate with an outside.

20. A wearable apparatus comprising:
a display unit including the organic light emitting apparatus according to claim 1;
an optical system that collects light of the display unit; and
a control device that controls display of the display unit.

21. A lighting apparatus comprising:
a light source including the organic light emitting apparatus according to claim 1; and
a housing provided with the light source.

22. A moving object comprising:
a display unit including the organic light emitting apparatus according to claim 1; and
an airframe provided with the display unit.

23. An image forming apparatus comprising:
a photosensitive member; and
an exposure light source configured to expose the photosensitive member,
wherein the exposure light source includes the organic light emitting apparatus according to claim 1.
